(19) United States
(12) Patent Application Publication
(10) Pub. No.: US 2025/0147425 A1
(43) Pub. Date: May 8, 2025

(54) STRIPPER COMPOSITION AND METHOD FOR FORMING PATTERN USING THE SAME

(71) Applicants: Samsung Display Co., LTD., Yongin-si (KR); ENF TECHNOLOGY CO., LTD., Yongin-si (KR)

(72) Inventors: KYU-SOON PARK, Yongin-si (KR); YOUNGROK KIM, Yongin-si (KR); JONG-HYUN CHOUNG, Yongin-si (KR); WOOJIN CHO, Yongin-si (KR); Sehoon KIM, Yongin-si (KR); Jongmo PARK, Yongin-si (KR); Joonsik YOON, Yongin-si (KR); Jangwoo CHO, Yongin-si (KR)

(21) Appl. No.: 18/934,215

(22) Filed: Oct. 31, 2024

(30) Foreign Application Priority Data
Nov. 3, 2023 (KR) 10-2023-0151021

(51) Int. Cl. G03F 7/42; C11D 3/20; C11D 3/30; C11D 3/32; G03F 7/30

(52) U.S. Cl. CPC G03F 7/425; C11D 3/2065; C11D 3/2068; C11D 3/30; C11D 3/32; G03F 7/3057; C11D 2111/16; C11D 2111/22

(57) ABSTRACT

Provided is a stripper composition and a method for forming a pattern using the same. The stripper composition includes, in set content ranges, an amine compound, a glycol compound, an aprotic polar solvent excluding N-methyl-2-pyrrolidone and N-methylformamide, and a first corrosion inhibitor represented by Formula 1. The stripper composition according to an embodiment may be used in a process of removing a photoresist pattern formed on a lower film, and may supply characteristics of an excellent stripping power for photoresist and prevention or reduction of damage of the lower film.

### CROSS-REFERENCE TO RELATED APPLICATIONS

The present application claims priority to and the benefit of Korean Patent Application No. 10-2023-0151021, filed on Nov. 3, 2023, in the Korean Intellectual Property Office, the entire content of which is hereby incorporated by reference.

### BACKGROUND

### 1. Field

Embodiments of the present disclosure herein relate to a stripper composition and a method for forming a pattern using the same, and, for example, to a stripper composition for removing photoresist and a method for forming a pattern using the same.

### 2. Description of the Related Art

A photolithography process using photoresist is performed in a semiconductor manufacturing process, or a panel process of a display device. For example, a photoresist pattern may be formed by forming a photoresist layer on a substrate, and exposing and developing the photoresist layer.

A stripper composition is used for removing the photoresist pattern in the photolithography process. Some environmentally regulated materials are included in a general stripper composition. Accordingly, development of technology for a stripper composition not including such environmentally regulated materials and having excellent photoresist pattern removal capability is needed.

### SUMMARY

Embodiments of the present disclosure provide a stripper composition having an improved stripping power for a photoresist pattern and an improved performance of dissolving the photoresist pattern while minimizing or reducing corrosion of a lower film of the photoresist pattern.

Embodiments of the present disclosure also provide a method for forming a pattern using the stripper composition described above.

An embodiment of the present disclosure provides a stripper composition including, with respect to a total weight of the stripper composition, an amine compound of about 1% by weight to about 30% by weight, a glycol compound of about 5% by weight to about 60% by weight, an aprotic polar solvent, excluding N-methyl-2-pyrrolidone and N-methylformamide, of about 20% by weight to about 70% by weight, and a first corrosion inhibitor, represented by Formula 1, of about 0.001% by weight to about 20% by weight.

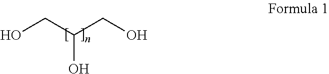

In Formula 1, n is an integer of 1 to 6.

In an embodiment, the amine compound may include at least one of monoethanolamine, N-methylethanolamine, N,N-diethanolamine, triethanolamine, propanolamine, aminoethanol, 2-(ethylamino)ethanol, 2-(methylamino)ethanol, methyldiethanolamine, dimethylethanolamine, diethylaminoethanol, 2-(2-aminoethylamino)ethanol, aminopropanol, aminobutanol, N-(methoxymethyl)diethylamine, (isobutoxymethyl)dimethylamine, 2-(2-aminoethoxy)ethanol, pyridine, methylpyridine, ethylpyridine, phenylpyridine, N-methyl-4-phenylpyridine, 4-dimethylaminopyridine, imidazole, benzimidazole, methylimidazole, 2-phenylbenzimidazole, triphenylimidazole, nicotine, nicotinic acid, nicotinamide, quinoline, hydroxyquinoline, pyrazine, pyrazole, pyridazine, purine, pyrrolidine, piperidine, 1,5-diazabicyclo[4.3.0]non-5-ene, 1,8-diazabicyclo[5.4.0] undec-7-ene, diethylenetriamine, triethylenetetramine, propylenediamine, tetraethylenepentamine, N,N-diethylethylenediamine, butanediamine, N-ethyl-ethylenediamine, propanediamine, hexanediamide, piperazine, N-methylpiperazine, N-ethylpiperazine, N-propylpiperazine, N-butylpiperazine, pentylpiperazine, hexylpiperazine, acryloylpiperazine, N-acryloyl-N′-methylpiperazine, hydroxyethylpiperazine, N-(2-aminoethyl) piperazine, N,N′-dimethylpiperazine, aniline, benzylamine, N,N′-dimethylaniline, or diphenylamine.

In an embodiment, the amine compound may include a primary amine compound.

In an embodiment, the amine compound may include at least one of an alkanol amine compound or an alkoxy amine compound, and a weight ratio of the alkanol amine compound and the alkoxy amine compound is 1:0.5 to 1:5.

In an embodiment, the amine compound may be included in an amount of more than about 5% by weight to about 30% by weight with respect to the total weight of the stripper composition.

In an embodiment, the glycol compound may include at least one of ethyleneglycolmonomethylether, ethyleneglycolmonoethyl ether, ethyleneglycolmonopropylether, ethyleneglycolmonobutylether, diethyleneglycol, diethyleneglycolmonomethylether, diethyleneglycolmonoethylether, diethyleneglycolmonopropylether, diethyleneglycolmonobutylether, propyleneglycolmonoethylether, propyleneglycolmonopropylether, propyleneglycolmonobutylether, dipropyleneglycolmonomethylether, dipropyleneglycolmonoethylether, dipropyleneglycolmonobutylether, dipropyleneglycoldimethylether, or dipropyleneglycoldiethylether.

In an embodiment, the aprotic polar solvent may include an amide-based solvent.

In an embodiment, the aprotic polar solvent may include at least one of formamide, N-ethylformamide, N,N-dimethylformamide, N,N-diethylformamide, N,N-dimethylpropionamide, dimethylsulfoxide, diethylsulfoxide, dipropylsulfoxide, sulfolane, 2-pyrrolidone, N-ethyl-2-pyrrolidone, or N-(2-hydroxyethyl)-2-pyrrolidone.

In an embodiment, the first corrosion inhibitor represented by Chemical Formula 1 may be included in an amount of about 5% by weight to about 10% by weight with respect to the total weight of the stripper composition.

In an embodiment, in Chemical Formula 1, n may be an integer of 1 to 4.

In an embodiment, the first corrosion inhibitor represented by Formula 1 may include at least one of glycerin, threitol, ribitol, xylitol, sorbitol, mannitol, or galactitol.

In an embodiment, the stripper composition may further include an additive, wherein the additive may include at least one of a surfactant, an antioxidant, or a stabilizer.

In an embodiment, the stripper composition may not include water.

In an embodiment, the stripper composition may have a specific gravity of about 1.01 or more.

In an embodiment of the inventive disclosure, a method for forming a pattern includes forming a photoresist pattern on a substrate on which a lower film is formed, forming a line pattern using the photoresist pattern, and removing the photoresist pattern by supplying a stripper composition, and the stripper composition described above is used in the removing of the photoresist pattern.

In an embodiment, the lower film may include a metal film including aluminum (Al), copper (Cu), or an alloy thereof, a nonmetallic oxide film such as a silicon oxide film or a silicon oxynitride film, or a combination thereof.

In an embodiment, the lower film may be a single film or a plurality of films.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a flowchart illustrating a method for forming a pattern according to an embodiment; and

FIGS. 2-6 are respectively cross-sectional views schematically illustrating a method for forming a pattern according to embodiments of the present disclosure.

### DETAILED DESCRIPTION

In embodiments of the present disclosure, various suitable modifications may be made and various suitable forms may be applied, and example embodiments will be illustrated in the drawings and described in more detail in the text. However, this is not intended to limit the present disclosure to a specific disclosure form, it should be understood to include all changes, equivalents, and substitutes included in the spirit and scope of the present disclosure.

In describing each drawing, similar reference numerals have been used for similar elements. In the accompanying drawings, the dimensions of the structures may be shown to be enlarged rather than actual size for clarity of the subject matter of the present disclosure. Terms such as first and second may be used to describe various components, but the components should not be limited by the terms. These terms are used only for the purpose of distinguishing one component from another component. For example, without departing from the scope of the present disclosure, a first component may be referred to as a second component, and similarly, a second component may be referred to as a first component. Singular expressions include plural expressions unless the context clearly indicates otherwise.

In the present application, terms such as “comprise” or “have” are intended to designate the presence of features, numbers, steps, actions, components, parts, or combinations thereof described in the specification. It should be understood that the possibility of the presence or addition of one or more other features or numbers, steps, actions, components, parts, or combinations thereof is not excluded in advance.

In the present application, when a part of a layer, film, region, plate, etc. is said to be “on” or “on” another part, it includes not only “directly above” another part, but also another part in the middle (e.g., between the part and the other part). Conversely, when a part such as a layer, film, region, or plate is said to be “under” or “under” another part, this includes not only the case where the other part is “directly below”, but also the case where there is another part in the middle (e.g., between the part and the other part). In the present application, the term “above” may include a case where it is provided not only at the top but also at the bottom.

Hereinafter, a stripper composition according to an embodiment of the present disclosure will be described.

The stripper composition according to an embodiment may be used so as to strip a photoresist pattern formed on a lower film thereof. The stripper composition according to an embodiment may be used so as to strip the photoresist pattern formed on a metal film and/or a nonmetallic oxide film. In embodiments, the stripper composition may be used so as to strip the photoresist pattern on the lower film, which is a combination of the metal film and the nonmetallic oxide film. The lower film of the photoresist pattern may include the metal film, the nonmetallic oxide film, or the combination thereof, and may be a single film or a plurality of films.

The stripper composition according to an embodiment of the present disclosure may include an amine compound, a glycol compound, an aprotic polar solvent, and a first corrosion inhibitor. The stripper composition according to an embodiment may further include an additive. However, the stripper composition according to an embodiment may not include N-methyl-2-pyrrolidone and N-methylformamide.

The amine compound included in the stripper composition according to an embodiment may serve to weaken a binding force of the photoresist pattern. For example, an intermolecular bonding in a cured photoresist resin may be broken or reduced by the amine compound. Accordingly, the stripper composition including the amine compound may have characteristics capable of easily stripping the photoresist pattern.

In an embodiment, the amine compound may include at least one hydroxy group, or may include an oxy group. For example, the amine compound may include an alkanol amine compound including one hydroxy group. The hydroxy group in the alkanol amine compound may be placed at a terminal end or a side chain of the amine compound. In embodiments, the amine compound may include an alkoxy amine compound including an alkoxy group. However, an embodiment of the present disclosure is not limited thereto, and the amine compound according to an embodiment may include a cyclic amine compound.

The amine compound according to an embodiment may include at least one of the alkanol amine compound or the alkoxy amine compound. For example, the amine compound may include the alkanol amine compound or the alkoxy amine compound. In embodiments, the amine compound may include both the alkanol amine compound and the alkoxy amine compound. When the stripper composition according to an embodiment includes both the alkanol amine compound and the alkoxy amine compound, the alkanol amine compound and the alkoxy amine compound may be included in a weight ratio of 1:0.5 to 1:5. For example, the alkanol amine compound and the alkoxy amine compound may be included in a weight ratio of 1:1 to 1:3.

In the present specification, the oxy group may mean a group in which an oxygen atom is bonded to an alkyl group or an aryl group. The oxy group may include an alkoxy group and an aryl oxy group. The alkoxy group may be straight, branched, or cyclic. A carbon number of the alkoxy group is not specially limited, but for example, may be 1 to 20 or 1 to 10. An example of the oxy group is a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but is not limited thereto.

In the present specification, the alkyl group may be straight, branched, or cyclic. A carbon number of the alkyl group is 1 to 50, 1 to 30, 1 to 20, 1 to 10, or 1 to 6. An example of the alkyl group may be a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but is not limited thereto.

In the present specification, the aryl group means an arbitrary functional group or substituent (e.g., any suitable functional group or substituent) derived from an aromatic hydrocarbon ring. The aryl group may be a monocyclic aryl group or a polycyclic aryl group. A ring-forming carbon number of the aryl group may be 6 to 30, 6 to 20, or 6 to 15. An example of the aryl group may be a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but is not limited thereto.

In the present specification, the cyclic amine compound means an amine compound derived from a cycle including at least one nitrogen (N) atom as a ring-forming atom. The cyclic amine compound may be derived from an aliphatic heterocycle or an aromatic heterocycle including at least one nitrogen (N) atom as a ring-forming atom. The aliphatic heterocycle and the aromatic heterocycle may be monocyclic or polycyclic.

In an embodiment, the amine compound may include at least one of monoethanolamine, methylethanolamine, diethanolamine, triethanolamine, propanolamine, aminoethanol, 2-(ethylamino)ethanol, 2-(methylamino)ethanol, N-methyldiethanolamine, N,N-dimethylethanolamine, 2-diethylaminoethanol, 2-(2-aminoethylamino)ethanol, aminoethanol (e.g. 1-amino-2-propanol, or 2-amino-1-propanol), aminobutanol (e.g. 4-amino-1-butanol), N-(methoxymethyl)-diethylamine, (isobutoxymethyl)dimethylamine, 2-(2-aminoethoxy)ethanol, pyridine, methylpyridine (e.g. 2-methylpyridine, or 4-methylpyridine), ethylpyridine (e.g. 2-ethylpyridine, or 4-ethylpyridine), phenylpyridine (e.g. 2-phenylpyridine, or 4-phenylpyridine), N-methyl-4-phenylpyridine, 4-dimethylaminopyridine, imidazole, benzimidazole, 4-methylimidazole, 2-phenylbenzimidazole, triphenylimidazole (e.g. 2,4,5-triphenylimidazole), nicotine, nicotinic acid, nicotinamide, quinoline, hydroxyquinoline (e.g. 8-hydroxyquinoline), pyrazine, pyrazole, pyridazine, purine, pyrrolidine, piperidine, 1,5-diazabicyclo[4.3.0]non-5-ene, 1,8-diazabicyclo[5.4.0] undec-7-ene, diethylenetriamine, triethylenetetramine, propylenediamine, tetraethylenepentamine, N,N-diethylethylenediamine, N,N′-diethylethylenediamine, butanediamine (e.g. 1,4-butanediamine), N-ethyl-ethylenediamine, propanediamine (e.g. 1,2-propanediamine, or 1,3-propanediamine), hexanediamide, piperazine, N-methylpiperazine, N-ethyl-piperazine, N-propylpiperazine, N-butylpiperazine, pentylpiperazine (e.g. 1-pentylpiperazine), hexylpiperazine (e.g. 1-hexylpiperazine), acryloylpiperazine, N-acryloyl-N′-methylpiperazine, hydroxyethylpiperazine, N-(2-aminoethyl) piperazine, N,N′-dimethylpiperazine, aniline, benzylamine, N,N-dimethylaniline, or diphenylamine.

The amine compound included in the stripper composition according to an embodiment may be a primary amine compound. For example, the stripper composition may include at least one of monoethanolamine, or 2-(2-aminoethoxy) ethanol as the amine compound. However, an embodiment of the present disclosure is not limited thereto. For example, at least one of a secondary amine compound, a tertiary amine compound, or a ring-type amine compound may be further included.

In an embodiment, a content of the amine compound may be about 1% by weight to about 30% by weight with respect to the total weight of the stripper composition. For example, the amine compound may be included in the stripper composition according to an embodiment in an amount of more than about 5% by weight to about 30% by weight, about 5% by weight to about 20% by weight, or about 5% by weight to about 15% by weight. When the content of the amine compound is less than about 1% by weight, it may be difficult for the stripper composition to sufficiently demonstrate a stripping performance, and a substrate stain may occur due to poor rinsing. When the content of the amine compound exceeds about 30% by weight, the lower film of the photoresist pattern may be damaged.

The stripper composition according to an embodiment of the present disclosure may include the glycol compound. The stripper composition may include at least one or two types (or kinds) of glycol compounds. The glycol compound may improve wettability for photoresist, and may improve solubility of the photoresist. In embodiments, the glycol compound may serve to prevent or reduce adsorption of the stripped photoresist again onto the lower film. Accordingly, the stripper composition according to an embodiment including the glycol compound may supply an excellent stripping power and an excellent rinsing power for the photoresist.

For example, the glycol compound may include at least one of ethyleneglycolmonomethylether, ethyleneglycolmonoethylether, ethyleneglycolmonopropylether, ethyleneglycolmonobutylether, diethyleneglycol, diethyleneglycolmonomethylether, diethyleneglycolmonoethylether (or ethyldiglycol) (EDG), diethyleneglycolmonopropylether, diethyleneglycolmonobutylether, propyleneglycolmonoethylether, propyleneglycolmonopropylether, propyleneglycolmonobutylether, dipropyleneglycolmonomethylether, dipropyleneglycolmonoethylether, dipropyleneglycolmonobutylether, dipropyleneglycoldimethylether, or dipropyleneglycoldiethylether.

The stripper composition according to an embodiment may include at least one of diethyleneglycolmonoethylether or dipropyleneglycolmonomethylether as the glycol compound. For example, the stripper composition according to an embodiment may include, as the glycol compound, diethyleneglycolmonoethylether or dipropyleneglycolmonomethylether. In embodiments, the glycol compound may include both diethyleneglycolmonoethylether and dipropyleneglycolmonomethylether.

When the stripper composition according to an embodiment includes, as the glycol compound, both diethyleneglycolmonoethylether and dipropyleneglycolmonomethylether, a content of the diethyleneglycolmonoethylether included in the stripper composition may be the same as, or greater than that of dipropyleneglycolmonomethylether. In an embodiment, the stripper composition may include diethyleneglycolmonoethylether and dipropyleneglycolmonomethylether in a weight ratio of 1:1 to 3:1. For example, the stripper composition may include diethyleneglycolmonoethylether and dipropyleneglycolmonomethylether in a weight ratio of 2:1 to 3:1. When diethyleneglycolmonoehtylether and dipropyleneglycolmonomethlyether are included in the stripper composition in the weight ratio, a stripping power and a rinsing power for the photoresist may be improved.

In an embodiment, a content of the glycol compound may be about 5% by weight to about 60% by weight with respect to the total weight of the stripper composition. For example, the glycol compound may be included in the stripper composition according to an embodiment in an amount of about 10% by weight to about 50% by weight, about 15% by weight to about 40% by weight, about 20% by weight to about 40% by weight, or about 25% by weight to about 40% by weight. When the glycol compound is included in the stripper composition in the above content ranges, a surface tension of the stripper composition may be reduced, thereby improving wettability for the photoresist, the stripping power for the photoresist, and solubility of the stripped photoresist. When the content of the glycol compound is less than about 5% by weight, it may be difficult for the stripper composition to demonstrate a stripping performance, and a substrate stain may occur due to poor rinsing. When the content of the glycol compound is more than about 60% by weight, solubility of the photoresist may be deteriorated or reduced.

The stripper composition according to an embodiment may include the aprotic polar solvent. The aprotic polar solvent may serve to improve the solubility of a photoresist pattern. In embodiments, the aprotic polar solvent may contribute to improvement of a specific gravity of the stripper composition. Accordingly, the stripper composition according to an embodiment including the aprotic polar solvent may easily remove the photoresist pattern modified by curing, thereby maximizing or increasing a stripping power and a cleaning power for the photoresist pattern.

As long as having excellent solubility of the stripped photoresist pattern, the aprotic polar solvent may be used without any special limitation, but may not include a hazardous material. For example, the aprotic polar solvent may not include N-methyl-2-pyrrolidinone and N-methylformamide, which are hazardous to the environment and a human body. For example, the stripper composition according to an embodiment may improve a performance of dissolving the stripped photoresist pattern while not using N-methyl-2-pyrrolidinone and N-methylformamide, which are hazardous materials, as the aprotic polar solvent.

For example, the aprotic polar solvent may include at least one of N-ethylformamide, formamide, N,N-dimethylformamide, N,N-diethylformamide, N,N-dimethylpropionamide, dimethylsulfoxide, diethylsulfoxide, dipropylsulfoxide, sulfolane, 2-pyrrolidone, N-ethyl-2-pyrrolidone, or N-(2-hydroxyethyl)-2-pyrrolidone. These may be used alone or in combination of two or more types (or kinds).

In an embodiment, the stripper composition may include an amide-based solvent as the aprotic polar solvent. For example, the aprotic polar solvent may include N-ethylformamide, but an embodiment of the present disclosure is not limited thereto. For example, the stripper composition according to an embodiment may further include at least one of formamide, N,N-dimethylformamide, N,N-diethylformamide, N,N-dimethylpropionamide, dimethylsulfoxide, diethylsulfoxide, dipropylsulfoxide, sulfolane, 2-pyrrolidone, N-ethyl-2-pyrrolidone, or N-(2-hydroxyethyl)-2-pyrrolidone.

In an embodiment, a content of the aprotic polar solvent may be about 20% by weight to about 70% by weight with respect to the total weight of the stripper composition. For example, the content of the aprotic polar solvent may be about 30% by weight to about 70% by weight, about 40% by weight to about 70% by weight, or about 40% by weight to about 60% by weight. When the aprotic polar solvent is included in the stripper composition in the content ranges described above, excellent stripping power for cured and/or modified photoresist and solubility of stripped photoresist may be maximized or increased. In embodiments, the specific gravity of the stripper composition may be equal to or more than about 1.01. When the content of the aprotic polar solvent is less than about 20% by weight, ability of removing the modified photoresist may not be sufficient. When the content of the aprotic polar solvent is more than about 70% by weight, a stripping performance may be deteriorated or reduced due to reduction of wettability of the stripper composition.

The stripper composition according to an embodiment may include a linear corrosion inhibitor. The linear corrosion inhibitor may be represented by Formula 1 below. The linear corrosion inhibitor represented by Formula 1 may excellently maintain a stripping power of the stripper composition while effectively suppressing or reducing corrosion of the lower film such as a metal film (for example, an aluminum line). In the present specification, the linear corrosion inhibitor may be referred to as “a first corrosion inhibitor”.

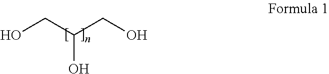

In Formula 1, n may be an integer of 1 to 6. For example, n may be an integer of 1 to 4. The first corrosion inhibitor represented by Chemical Formula 1 includes all of a racemate and a stereoisomer thereof.

In an embodiment, the first corrosion inhibitor may include at least one of glycerin, threitol, ribitol, xylitol, sorbitol, mannitol, or galactitol. For example, the stripper composition according to an embodiment may include, as the first corrosion inhibitor, glycerin, threitol, ribitol, xylitol, sorbitol, mannitol, or galactitol. However, an embodiment of the present disclosure is not limited thereto.

In an embodiment, a content of the first corrosion inhibitor may be about 0.001% by weight to about 20% by weight with respect to the total weight of the stripper composition. For example, the first corrosion inhibitor may be included in the stripper composition in an amount of about 0.01% by weight to about 10% by weight, about 0.1% by weight to about 10% by weight, about 0.01% by weight to about 5% by weight, about 0.01% by weight to about 3% by weight, about 5% by weight to about 10% by weight, or about 3% by weight to about 5% by weight. The first corrosion inhibitor may suppress or reduce corrosion of the lower film while supplying a sufficient stripping power for the photoresist pattern within the content ranges described above. For example, the stripper composition according to an embodiment including the first corrosion inhibitor within the content ranges described above may selectively rapidly strip only the photoresist pattern while not leaving a stain and/or damage on the lower film thereof. When the content of the first corrosion inhibitor is less than about 0.001% by weight, a corrosion inhibition power of the metal film and the oxide film, which are the lower film, may not be sufficiently demonstrated. When the content of the first corrosion inhibitor is more than about 20% by weight, the stripping power for the photoresist pattern may be deteriorated or reduced.

The stripper composition according to an embodiment may further include the additive as well as the amine compound, the glycol compound, the aprotic polar solvent, and the first corrosion inhibitor. The additive may further include at least one of a surfactant, an antioxidant, or a stabilizer.

The surfactant may be included in the stripper composition to improve wettability and bubble characteristics of the stripper composition, and to increase solubility of ingredients included in the stripper composition. The surfactant may include at least one of a non-ionic surfactant, an anionic surfactant, a cationic surfactant, or an amphoteric surfactant. The surfactant may be used without any special limitation as long as it does not deteriorate or reduce (or substantially deteriorate or reduce) the performance of the stripper composition according to an embodiment.

In an embodiment, the surfactant may be added in an amount of more than about 0.0005% by weight to less than about 5% by weight with respect to the total weight of the stripper composition. For example, the surfactant may be added to the stripper composition according to an embodiment in an amount of about 0.001% by weight to about 2% by weight with respect to the total weight of the stripper composition. When the content of the surfactant is equal to or less than about 0.0005% by weight with respect to the total weight of the stripper composition, an effect of improving wettability of the stripper composition, and/or the like may not be expected, and when the content of the surfactant is equal to or more than about 5% by weight, a solubility limitation, and/or a process limitation caused by generation of excessive bubbles may occur.

The antioxidant may be included in the stripper composition according to an embodiment so as to protect the metal and/or the metal compound used as a material of a semiconductor element. The antioxidant may be used without any limitation as long as being used in a stripper composition technology field, and may be added in an amount of about 0.01% by weight to about 10% by weight with respect to the total weight of the stripper composition.

The stabilizer may be included so as to suppress or reduce generation of a side reaction and/or a by-product that may be caused by an unnecessary reaction in an application subject.

The stripper composition according to an embodiment of the present disclosure may not include water. For example, the stripper composition according to an embodiment may be a non-aqueous stripper composition. The water may include deionized water (ultrapure water).

The stripper composition according to an embodiment may be used in a process of manufacturing an electronic device, for example, in a process of removing a photoresist pattern thereof. As an example, the stripper composition according to an embodiment may be used in a process of manufacturing an array substrate of a process of manufacturing a display device, and may be used in a process of removing the photoresist pattern formed on the metal film and/or the nonmetalic oxide film.

In an embodiment, the photoresist pattern may be removed through any suitable stripping apparatus using the stripper composition. Polyvinylbutyral may be applied as a glass adhesive in the stripping apparatus. When the polyvinylbutyral is exposed in the stripper composition for a long time, the polyvinylbutyral may melt to fall on, during the process, a substrate on which the lower film is formed. In this case, when the polyvinylbutyral has a greater specific gravity than the stripper composition, the polyvinylbutyral may be adsorbed on the substrate to be generated as a foreign matter.

In order to prevent or reduce generation of the polyvinylbutyral as the foreign matter, the stripper composition according to an embodiment of the present disclosure may have a greater specific gravity than the polyvinylbutyral. For example, the stripper composition according to an embodiment may include the protic polar solvent and the aprotic polar solvent described above to have a greater specific gravity than the polyvinylbutyral. For example, because the polyvinylbutyral has a specific gravity of about 1.00, the stripper composition according to an embodiment may have a specific gravity of about 1.01 or more. Accordingly, when the stripper composition according to an embodiment is used, adsorption of the polyvinylbutyral onto the substrate on which the lower film is formed during a process may be prevented or reduced, thereby reducing a product failure risk due to generation of the foreign matter.

Hereinafter, a method for manufacturing an array substrate according to an embodiment of the present disclosure will be described with reference to the drawings. The method for manufacturing an array substrate may use a stripper composition according to an embodiment described above.

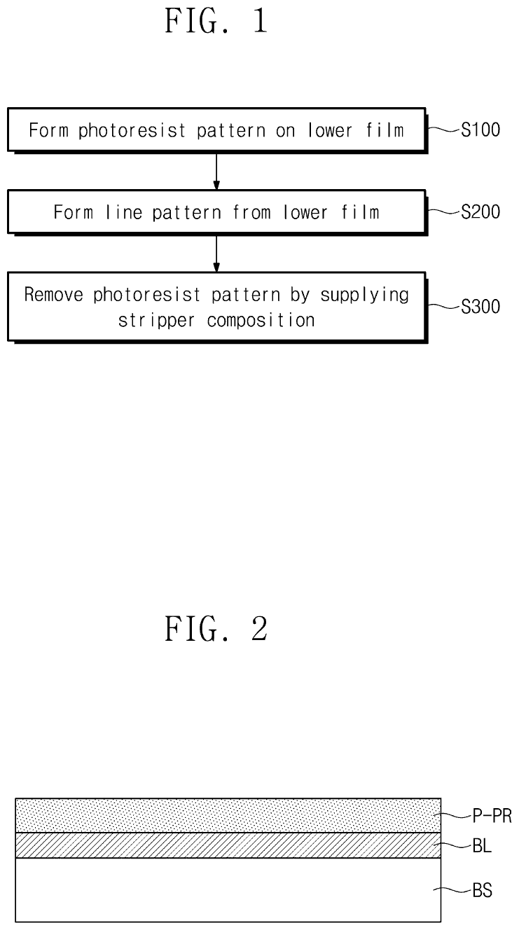

FIG. 1 is a flowchart schematically illustrating a method for forming a pattern according to an embodiment. FIGS. 2-6 schematically illustrate a method for forming a pattern according to an embodiment. Configurations illustrated in FIGS. 2-6 may be illustrated as enlarged, and may have sizes different from real sizes thereof.

Referring to FIG. 1, the method for forming a pattern according to an embodiment may include an operation (S100) of forming a photoresist pattern on a lower film, an operation (S200) of forming a line pattern from the lower film, and an operation (S300) of removing the photoresist pattern by supplying a stripper composition.

Referring to FIGS. 1 and 2, a lower film BL may be formed on a substrate BS, and a photoresist film P-PR may be formed on the lower film BL. The substrate BS may be a member that supplies a base surface on which the lower film BL is provided. The substrate BS may be a glass substrate, a metal substrate, a plastic substrate, and/or the like. However, an embodiment of the present disclosure is not limited thereto, and the substrate BS may be an inorganic layer, an organic layer, or a composite material layer. In embodiments, the substrate BS may include a semiconductor substrate such as a silicon wafer.

The lower film BL may include a metal film, a nonmetallic oxide film, or a combination thereof. For example, the metal film may include metal such as aluminum (Al), copper (Cu), and/or an alloy thereof. For example, the nonmetalic oxide film may be a silicon oxide film, a silicon oxynitride film, and/or the like, but an embodiment of the present disclosure is not limited thereto.

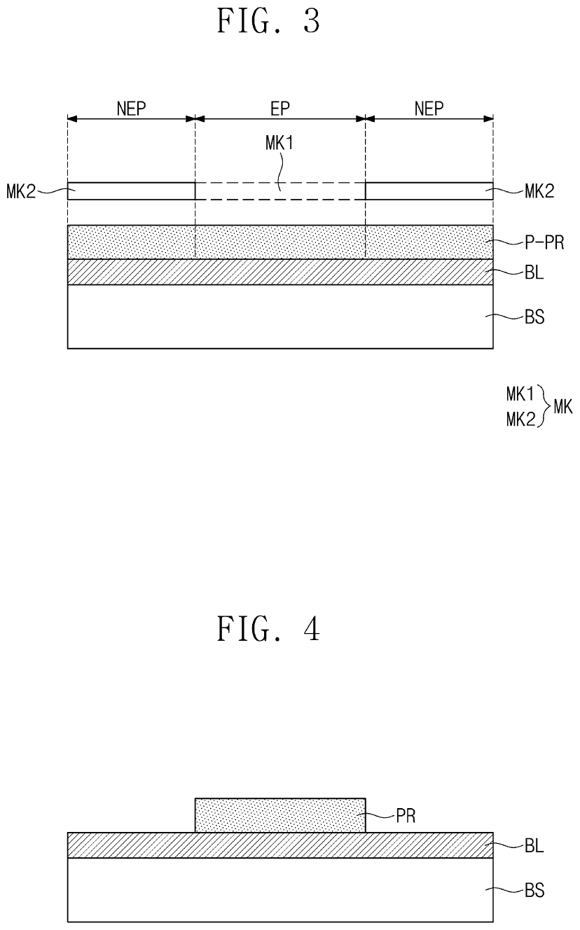

The photoresist film P-PR may be formed by applying and drying a photoresist composition on the lower film BL. In the present embodiment, it is described as an example that a negative type photoresist composition of which polymer curing is derived in an exposure portion EP (see FIG. 3) is applied on the lower film BL, but an embodiment of the present disclosure is not limited thereto, and the photoresist film P-PR may be formed by applying, on the lower film BL, a positive-type photoresist composition of which polymer softening is derived in the exposure portion EP (see FIG. 3).

Referring to FIG. 3, an exposure process of the photoresist film P-PR may be performed using a mask MK. The mask MK may be spaced apart from the substrate BS on which the photoresist film P-PR is formed. The mask MK may include a transmission region MK1 and a light-blocking region MK2 to selectively transmit light (for example, UV light) incident from the top of the mask MK. Accordingly, the exposure portion EP of the photoresist film P-PR overlapping the transmission region MK1 of the mask MK may be exposed to the light to be cross-linked/cured. In embodiments, a non-exposure portion NEP of the photoresist film P-PR overlapping the light-blocking region MK2 of the mask MK may not be cured.

Referring to FIGS. 3 and 4 together, the non-exposure portion NEP of the photoresist film P-PR may be removed using a developer. For example, the non-exposure portion NEP of the photoresist film P-PR not transmitted by (or exposed to) the light due to the light-blocking region MK2 of the mask MK may be completely removed by the developer, and thus a surface of the lower film BL may be exposed. In embodiments, the exposure portion EP of the photoresist film P-PR may remain on the lower film BL to form a photoresist pattern PR.

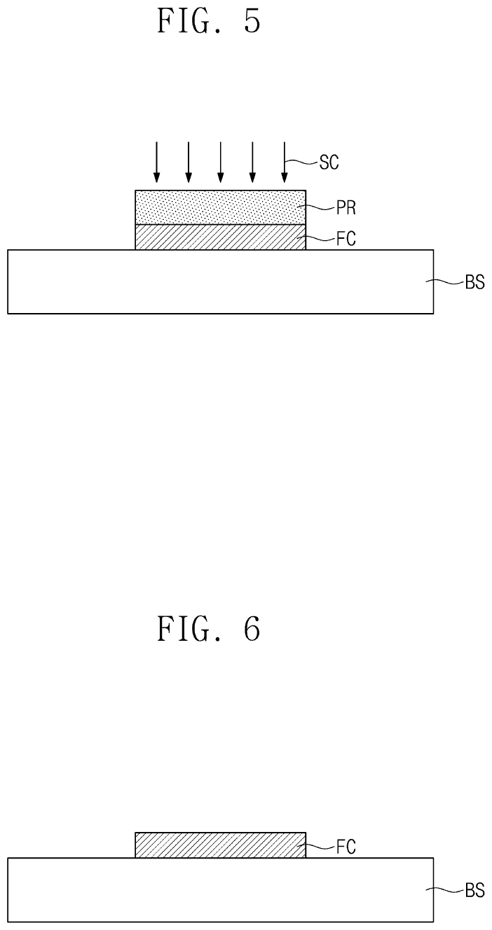

In an embodiment, the photoresist pattern PR may be used as an etching mask for patterning the lower film BL. For example, an etchant may be supplied on the lower film BL, and the lower film BL may be etched using the supplied etchant. The lower film BL may not be etched due to the photoresist pattern PR in a region on which the photoresist pattern PR is provided, and the lower film BL may be etched in a region on which the photoresist pattern PR is not provided, so that a line pattern FC may be formed like what is illustrated in FIG. 5. For example, the line pattern FC is formed from the lower film BL by the etching process. The etchant used in a process of etching the lower film BL is not limited to any one embodiment, and may be applied to the subject matter of the present disclosure without any special limitation as long as being capable of etching a film including the metal film, the nonmetallic oxide film, or a combination thereof.

Referring to FIGS. 5-6, the photoresist pattern PR on the line pattern FC may be removed by supplying the stripper composition SC according to an embodiment described above.

For example, in the operation of removing the photoresist pattern PR, stripping of the photoresist pattern PR may begin by using the stripper composition SC according to an embodiment. As described above, the stripper composition SC according to an embodiment may include the amine compound, the glycol compound, the aprotic polar solvent, and the first corrosion inhibitor. In embodiments, the stripper composition may further include an additive including at least one of a surfactant, an antioxidant, or a stabilizer. The aprotic polar solvent may not include N-methyl-2-pyrrolidone or N-methylformamide. The first corrosion inhibitor may be represented by Formula 1.

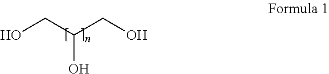

In Formula 1, n may be an integer of 1 to 6, but an embodiment of the present disclosure is not limited thereto.

In the stripper composition SC according to an embodiment, the amine compound may be in rapid contact with the photoresist pattern without loss (or substantially without loss) caused by volatilization, and removed photoresist ingredients may be rapidly dissolved. Accordingly, the stripper composition SC according to an embodiment may suitably or sufficiently swell and remove the photoresist pattern PR, and may remove the photoresist pattern PR from the substrate BS. Because the stripper composition SC described above has an improved solubility of the photoresist, a stripping process may be performed using the stripper composition SC according to an embodiment while not substantially leaving a residue of the photoresist pattern PR on the line pattern FC, and not damaging the line pattern FC.

In the method for forming a pattern according to an embodiment, the operation of removing the photoresist pattern PR may include a rinse process of cleaning the substrate BS on which the line pattern FC is formed. The rinse process may be a process of cleaning, with water, the substrate BS on which the line pattern FC is formed. For example, after the photoresist pattern PR is stripped from the substrate BS on which the line pattern FC is formed using the stripper composition SC described above, the substrate BS may be cleaned with water. The method for forming a pattern according to an embodiment may not leave the residue of the photoresist pattern PR and the stripper composition SC on the line pattern FC through the rinse process. In the method for forming a pattern according to an embodiment, the stripper composition SC described above may be used in removing the photoresist pattern PR, and the stripper composition SC may have excellent water-replaceability, thereby preventing or reducing occurrence of a stain on the substrate BS on which the line pattern FC is formed.

The line pattern FC capable of using the stripper composition SC according to embodiments of the present disclosure is not specially limited, and may be a single film, or a plurality of films. The line pattern FC may be a line for a gate electrode, a source electrode, or a drain electrode that constitutes a thin-film transistor of a display device.

A stripper composition according to an embodiment of the present disclosure may remove photoresist in a short amount of time by demonstrating an excellent stripping power for the photoresist while not damaging a lower film including a metal film, a nonmetallic oxide film, or a combination thereof. In embodiments, the stripper composition has an excellent dissolving power of the photoresist, thereby improving economic efficiency through increase of the number of processed sheets, and has an excellent cleaning power, thereby not leaving residual solution and/or surface impurities after stripping the photoresist pattern. Due to these effects, the stripper composition according to embodiments of the present disclosure may contribute to a yield increase in a process of manufacturing a semiconductor and a display device.

Hereinafter, while referring to Examples and Comparative Examples, a stripper composition according to embodiments of the present disclosure and a line manufactured using the same will be further described. In addition, the Examples described hereinafter are examples for helping understand the subject matter of the present disclosure, and a scope of the present disclosure is not limited thereto.

### EXAMPLE

### 1. Manufacturing the Stripper Composition

Stripper compositions of Examples 1 to 16 according to embodiments of the present disclosure and stripper compositions of Comparative Examples 1 to 9 were manufactured according to compositions and contents described in Table 1 below. A unit representing a content of each component in Table 1 is weight percent with respect to 100% by weight of the total weight of the stripper composition.

TABLE 1

| | Amine | | Glycol | | Aprotic polar | | First corrosion | |
|---|---|---|---|---|---|---|---|---|
| | compound | | compound | | solvent | | inhibitor | |
| Classification | Type | Content | Type | Content | Type | Content | Type | Content |
| Example 1 | MEA | 10 | EDG | 30 | NEF | 50 | Glycerin | 10 |
| Example 2 | AEE | 10 | EDG | 30 | NEF | 50 | Glycerin | 10 |
| Example 3 | MEA | 5 | DPM | 20 | NEF | 60 | Glycerin | 10 |
| | AEE | 5 | | | | | | |
| Example 4 | MEA | 3 | EDG | 20 | NEF | 50 | Glycerin | 10 |
| | AEE | 7 | DPM | 10 | | | | |
| Example 5 | AEE | 10 | EDG | 30 | NEF | 50 | Xylitol | 10 |
| Example 6 | MEA | 10 | DPM | 30 | NEF | 50 | Threitol | 10 |
| Example 7 | AEE | 10 | EDG | 30 | NEF | 50 | Libitol | 10 |
| Example 8 | MEA | 10 | DPM | 30 | NEF | 50 | Sorbitol | 10 |
| Example 9 | AEE | 10 | EDG | 30 | NEF | 50 | Mannitol | 10 |
| Example 10 | MEA | 10 | DPM | 30 | NEF | 50 | Galactitol | 10 |
| Example 11 | MEA | 1 | EDG | 39 | NEF | 50 | Glycerin | 10 |
| Example 12 | MEA | 20 | EDG | 30 | NEF | 30 | Glycerin | 20 |
| Example 13 | MEA | 10 | EDG | 5 | NEF | 75 | Glycerin | 10 |
| Example 14 | MEA | 10 | EDG | 60 | NEF | 20 | Glycerin | 10 |
| Example 15 | MEA | 10 | EDG | 10 | NEF | 70 | Glycerin | 10 |
| Example 16 | MEA | 10 | EDG | 20 | NEF | 50 | Glycerin | 20 |
| Comparative Example 1 | MEA | 5 | — | — | NEF | 85 | Glycerin | 10 |
| Comparative Example 2 | MEA | 5 | EDG | 45 | NMF | 50 | — | — |
| Comparative Example 3 | — | — | EDG | 40 | NEF | 50 | Glycerin | 10 |
| Comparative Example 4 | MEA | 10 | EDG | 90 | — | — | — | — |
| Comparative Example 5 | AEE | 10 | EDG | 40 | NMF | 50 | — | — |
| Comparative Example 6 | AEE | 10 | EDG | 90 | — | — | — | — |
| Comparative Example 7 | MEA | 0.5 | EDG | 14 | NEF | 85.4995 | Glycerin | 0.0005 |
| Comparative Example 8 | MEA | 31 | EDG | 9 | NEF | 50 | Glycerin | 10 |
| Comparative Example 9 | MEA | 10 | EDG | 4.5 | NEF | 85.4995 | Glycerin | 0.0005 |

MEA: monoethanolamine
AEE: 2-(2-aminoethoxy)ethanol
EDG: diethyleneglycolmonoethylether
DPM: dipropyleneglycolmonomethylether
NEF: N-ethylformamide
NMF: N-methylformamide

### 2. Evaluation of Performances of the Stripper Compositions

### 1) Evaluation of a Stripping Power

Photoresist stripping powers of the stripper compositions of Examples 1 to 16 and Comparative Examples 1 to 9 were evaluated. Experimental specimens were prepared by hard baking (H/B) for about 10 minutes at about 160° C. after applying photoresist (AZEM, DTR-300) of about 1.5 μm on a glass substrate. A time required for being completely stripped by each stripper composition of the Examples and the Comparative Examples was measured under a spray pressure condition of about 0.4 kgf using a single-wafer spray type stripping apparatus maintained at a temperature of about 60° C., and evaluation results thereof are shown in Table 2. In this case, whether or not the photoresist was stripped was confirmed by irradiating ultraviolet light on the glass substrate and observing whether or not the photoresist remained.

### 2) Evaluation of a Solubility

Photoresist solubilities of the stripper compositions of Examples 1 to 16 and Comparative Examples 1 to 9 were evaluated. Photoresist powders were prepared by drying the photoresist (AZEM, DTR-300) on a hotplate at about 160° C. for about 4 hours. The solubilities were evaluated by passing through a filter of about 10 μm

(PTFE having a pore of about 10 μm) after dissolving by inserting the dried photoresist powders in the solid content of about 2% by weight into each stripper composition maintained at a temperature of about 60° C., and stirring for about 20 minutes under a stirring condition of about 300 rpm. The results are shown in Table 2.

The weight percentage of the photoresist is set to 100% by weight in a case

in which the photoresist is completely dissolved within about 20 minutes and the remaining amount thereof is not measured after filtering. Here, because a higher weight percentage value means that a larger amount of photoresist may be dissolved, it may be said that the higher weight percent value means the greater number of processed photoresist sheets.

The solubility may be calculated by the following equation.

$$Solubility ( \text{} \% ) = [ ( a content of photoresist used in a solid content of about 2 \% by weight - a content of photoresit left in the filter ) / the content of the photoresit used in the solid content of about 2 \% by weight ] \times 100 \qquad Equation 1$$

### 3) Evaluation of a Rinsing Power

Rinsing powers, on a substrate, of the stripper compositions of Example 1 to 16 and Comparative Example 1 to 9 were evaluated. A substrate immersed for about 1 minute in each of the stripping compositions of Example 1 to 16 and Comparative Examples of 1 to 9 was taken out and over-dried for about 1 minute using an air knife. After rinsing the over-dried substrate with water, a stain of the substrate was visually confirmed. A stripper composition having good water-replaceability also has a good rinsing power so that a degree of the stain is weak. Evaluation results of the rinsing powers are shown in Table 2 below, and the evaluation criteria of the rinsing powers are as follows.

### Evaluation Criteria

⊚: very good
○: good
Δ: a stain occurs
X: stains severely occur

### 4) Evaluation of an Aluminum Damage

Degrees of the damage of aluminum, on the substrate, by solutions of the stripper compositions of the Examples and Comparative Examples diluted to about 90% by weight with deionized water (DI) are evaluated. The results are shown in Table 2.

TABLE 2

| | Stripping | | | Aluminum |
|---|---|---|---|---|
| | power | | Rinsing | damage |
| Classification | (sec) | Solubility | power | (nm) |
| Example 1 | 5 | 99.99 | ⊚ | 0 |
| Example 2 | 7 | 99.99 | ⊚ | 0 |
| Example 3 | 5 | 99.99 | ◯ | 0 |
| Example 4 | 5 | 99.99 | ⊚ | 0 |
| Example 5 | 10 | 98.99 | ◯ | 0 |
| Example 6 | 10 | 98.99 | ◯ | 0 |
| Example 7 | 10 | 99.53 | ◯ | 0 |
| Example 8 | 10 | 99.65 | ◯ | 0 |
| Example 9 | 10 | 99.53 | ◯ | 0 |
| Example 10 | 10 | 99.15 | ◯ | 0 |
| Example 11 | 15 | 99.99 | ⊚ | 0 |
| Example 12 | 5 | 99.99 | ⊚ | 0 |
| Example 13 | 10 | 99.99 | ◯ | 0 |
| Example 14 | 10 | 99.71 | ⊚ | 0 |
| Example 15 | 10 | 99.99 | ⊚ | 0 |
| Example 16 | 15 | 99.99 | ⊚ | 0 |
| Comparative | 10 | 98.53 | Δ | 0 |
| Example 1 | | | | |
| Comparative | 10 | 95.48 | ◯ | 200 |
| Example 2 | | | | |
| Comparative | 60 | 88.77 | ◯ | 0 |
| Example 3 | | | | |
| Comparative | 15 | 95.87 | ◯ | 430 |
| Example 4 | | | | |
| Comparative | 10 | 99.99 | ◯ | 330 |
| Example 5 | | | | |
| Comparative | 15 | 92.38 | ◯ | 300 |
| Example 6 | | | | |
| Comparative | 30 | 99.19 | ◯ | 170 |
| Example 7 | | | | |
| Comparative | 10 | 99.99 | ◯ | 530 |
| Example 8 | | | | |
| Comparative | 20 | 99.99 | Δ | 220 |
| Example 9 | | | | |

Referring to Table 2, it may be confirmed that the stripper compositions of Example 1 to 16 have excellent stripping powers, solubilities, and rinsing powers without any aluminum damage.

On the other hand, Comparative Example 1 not including the glycol compound shows a deteriorated rinsing power.

It may be seen that in Comparative Examples 2 and 5 not including the first corrosion inhibitor (linear corrosion inhibitor), aluminum, which is the lower film, was damaged. In addition, it may be confirmed that the stripper composition of Comparative Example 2 has a more deteriorated solubility for the photoresist than the stripper compositions of the Examples.

It may be seen that the stripper composition of Comparative Example 3 not including the amine compound has still more deteriorated stripping power and solubility than the stripper compositions of the Examples.

It may be confirmed that the stripper compositions of Comparative Examples 4 and 6 not including the aprotic polar solvent and the linear corrosion inhibitor have more deteriorated stripping power and solubilities, and greater aluminum damage than the stripper compositions of the Examples.

It may be seen that the stripper composition of Comparative Example 7, which excessively includes the aprotic polar solvent of equal to or more than about 85% by weight, and the amine compound of less than about 1% by weight, and thus, has a more deteriorated stripping power and provides more aluminum damage than the stripper composition of the Examples.

It may be seen that the stripper composition of Comparative Example 8, which includes the amine compound of more than about 30% by weight, provides more aluminum damage than the stripper compositions of the Examples. In addition, the stripper composition of Comparative Example 9, including the glycol compound of about 4.5% by weight, has a more deteriorated stripping power and provides more aluminum damage than the stripper compositions of the Examples.

A stripper composition according to an embodiment may demonstrate an excellent stripping power for photoresist without any damage of a lower film to remove the photoresist in a short amount of time. In addition, the stripper composition according to an embodiment may have an excellent solubility of the photoresist and an excellent rinsing power, thereby not leaving a residual solution or surface impurities after stripping the photoresist.

A method for manufacturing a pattern according to an embodiment may use the stripper composition described above, thereby improving a rate and efficiency of stripping the photoresist.

In the above, description has been made with reference to example embodiments of the present disclosure, but those skilled in the art or those of ordinary skill in the relevant technical field may understand that various modifications and changes may be made to the subject matter of the present disclosure within the spirit and scope of the present disclosure as defined in the appended claims, and equivalents thereof.

Therefore, the technical scope of the present disclosure is not limited to the contents described in the detailed description of the specification, but should be determined by the appended claims, and equivalents thereof.

What is claimed is:

1. A stripper composition comprising:
with respect to a total weight of the stripper composition,
an amine compound of about 1% by weight to about 30% by weight;
a glycol compound of about 5% by weight to about 60% by weight;
an aprotic polar solvent, excluding N-methyl-2-pyrrolidone and N-methylformamide, of about 20% by weight to about 70% by weight; and
a first corrosion inhibitor, represented by Formula 1, of about 0.001% by weight to about 20% by weight: 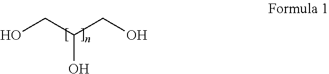
in Formula 1, n is an integer of 1 to 6.

2. The stripper composition of claim 1, wherein the amine compound comprises at least one of monoethanolamine, N-methylethanolamine, N,N-diethanolamine, triethanolamine, propanolamine, aminoethanol, 2-(ethylamino)ethanol, 2-(methylamino)ethanol, methyldiethanolamine, dimethylethanolamine, diethylaminoethanol, 2-(2-aminoethylamino)ethanol, aminopropanol, aminobutanol, N-(methoxymethyl)diethylamine, (isobutoxymethyl)dimethylamine, 2-(2-aminoethoxy)ethanol, pyridine, methylpyridine, ethylpyridine, phenylpyridine, N-methyl-4-phenylpyridine, 4-dimethylaminopyridine, imidazole, benzimidazole, 4-methylimidazole, 2-phenylbenzimidazole, triphenylimidazole, nicotine, nicotinic acid, nicotinicacidamide, quinoline, hydroxyquinoline, pyrazine, pyrazole, pyridazine, purine, pyrrolidine, piperidine, 1,5-diazabicyclo[4.3.0] non-5-ene, 1,8-diazabicyclo [5.4.0] undec-7-ene, diethylenetriamine, triethylenetetramine, propylenediamine, tetraethylenepentamine, N,N-diethylethylenediamine, butanediamine, N-ethyl-ethylenediamine, propanediamine, hexanediamide, piperazine, N-methylpiperazine, N-ethylpiperazine, N-propylpiperazine, N-butylpiperazine, pentylpiperazine, hexylpiperazine, acryloylpiperazine, N-acryloyl-N′-methylpiperazine, hydroxyethylpiperazine, N-(2-aminoethyl) piperazine, N,N′-dimethylpiperazine, aniline, benzylamine, N,N′-dimethylaniline, or diphenylamine.

3. The stripper composition of claim 1, wherein the amine compound comprises a primary amine compound.

4. The stripper composition of claim 1, wherein the amine compound comprises at least one of an alkanol amine compound or an alkoxy amine compound.

5. The stripper composition of claim 4, wherein a weight ratio of the alkanol amine compound and the alkoxy amine compound is 1:0.5 to 1:5.

6. The stripper composition of claim 1, wherein the amine compound is included in an amount of more than about 5% by weight to about 30% by weight with respect to the total weight of the stripper composition.

7. The stripper composition of claim 1, wherein the glycol compound comprises at least one of ethyleneglycolmonomethylether, ethyleneglycolmonoethyl ether, ethyleneglycolmonopropylether, ethyleneglycolmonobutylether, diethyleneglycol, diethyleneglycolmonomethylether, diethyleneglycolmonoethylether, diethyleneglycolmonopropylether, diethyleneglycolmonobutylether, propyleneglycolmonoethylether, propyleneglycolmonopropylether, propyleneglycolmonobutylether, dipropyleneglycolmonomethylether, dipropyleneglycolmonoethylether, dipropyleneglycolmonobutylether, dipropyleneglycoldimethylether, or dipropyleneglycoldiethylether.

8. The stripper composition of claim 1, wherein the aprotic polar solvent comprises an amide-based solvent.

9. The stripper composition of claim 1, wherein the aprotic polar solvent comprises at least one of formamide, N-ethylformamide, N,N-dimethylformamide, N,N-diethylformamide, N,N-dimethylpropionamide, dimethylsulfoxide, diethylsulfoxide, dipropylsulfoxide, sulfolane, pyrrolidone, ethylpyrrolidone, or N-(2-hydroxyethyl)-2-pyrrolidone.

10. The stripper composition of claim 1, wherein the first corrosion inhibitor represented by Formula 1 is included in an amount of about 5% by weight to about 10% by weight with respect to the total weight of the stripper composition.

11. The stripper composition of claim 1, wherein in Formula 1, n is an integer of 1 to 4.

12. The stripper composition of claim 11, wherein the first corrosion inhibitor represented by Formula 1 comprises at least one of glycerin, threitol, ribitol, xylitol, sorbitol, mannitol, or galactitol.

13. The stripper composition of claim 1, further comprising an additive, wherein the additive includes at least one of a surfactant, an antioxidant, or a stabilizer.

14. The stripper composition of claim 1, wherein the stripper composition does not comprise water.

15. The stripper composition of claim 1, wherein the stripper composition has a specific gravity of about 1.01 or more.

16. A method for forming a pattern, the method comprising:
forming a photoresist pattern on a substrate on which a lower film is formed;
forming a line pattern using the photoresist pattern; and
removing the photoresist pattern by supplying a stripper composition,
wherein the stripper composition comprises, with respect to a total weight of the stripper composition,
an amine compound of about 1% by weight to about 30% by weight;
a glycol compound of about 5% by weight to about 60% by weight;
an aprotic polar solvent, excluding N-methyl-2-pyrrolidone and N-methylformamide, of about 20% by weight to about 70% by weight; and
a first corrosion inhibitor, represented by Formula 1, of about 0.001% by weight to 20% by weight, 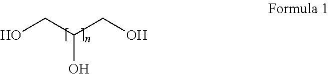
in Formula 1, n is an integer of 1 to 6.

17. The method of claim 16, wherein the lower film comprises:
a metal film comprising aluminum (Al), copper (Cu), or an alloy thereof;
a metal oxide film such as a silicon oxide film or a silicon oxynitride film; or
a combination thereof.

18. The method of claim 16, wherein the lower film is a single film or a plurality of films.

19. The method of claim 16, wherein the aprotic polar solvent comprises N-ethylformamide.

20. The method of claim 16, wherein the amine compound comprises at least one of monoethanolamine or 2-(2-aminoethoxy)ethanol.
